(19) United States
(12) Patent Application Publication
(10) Pub. No.: US 2022/0114421 A1
(43) Pub. Date: Apr. 14, 2022

(54) METHOD FOR ESTIMATING THE CAPACITY OF LITHIUM BATTERY BASED ON CONVOLUTION LONG-SHORT-TERM MEMORY NEURAL NETWORK

(71) Applicant: CHONGQING UNVERSITY OF POSTS AND TELECOMMUNICATIONS, Chongqing (CN)

(72) Inventors: Penghua Li, Chongqing (CN); Zijian Zhang, Chongqing (CN); Ping Wang, Chongqing (CN); Yi Chai, Chongqing (CN); Xiaosong Hu, Chongqing (CN); Liping Chen, Chongqing (CN); Jie Hou, Chongqing (CN); Anyu Cheng, Chongqing (CN)

(73) Assignee: CHONGQING UNVERSITY OF POSTS AND TELECOMMUNICATIONS, Chongqing (CN)

(21) Appl. No.: 17/261,874

(22) PCT Filed: Jan. 14, 2020
(86) PCT No.: PCT/CN2020/072069

§ 371 Date: Jan. 21, 2021

(30) Foreign Application Priority Data
Jan. 8, 2020 (CN) 202010017957.2

(51) Int. Cl. G06N 3/04; G06N 3/08; G01R 31/00; G01R 31/367; G01R 31/396

(52) U.S. Cl. CPC G06N 3/0454; G06N 3/086; G01R 31/396; G01R 31/367; G01R 31/006

(57) ABSTRACT

The present invention relates to a method of estimating lithium battery capacity based on a convolution long-short-term memory neural network (CNN-LSTM). The present invention obtains a model that lithium battery capacity estimation through the four steps: processing a lithium battery's data, selecting parameters of an improved convolution long-short-term memory neural network using a genetic algorithm, training the improved CNN-LSTM, and testing model. Hyper-parameters of the improved CNN-LSTM are optimized using the genetic algorithm. Using the convolution neural network to extract the spatial features of lithium battery charge and discharge data, and then input these features into the improved long-short-term memory neural network to extract temporal features, estimated capacity is output through a fully connected layer finally. The present invention overcomes the limitation of the traditional model-based algorithm overly relying on the battery model and has the engineering application prospect.

### TECHNICAL FIELD

The present invention belongs to lithium batteries' technical field and relates to a method of lithium battery capacity estimation based on a convolution long-short-term memory neural network.

### BACKGROUND

The emergence of low-cost, high-energy, and long-life novel power lithium batteries, and the generation of motor controllers based on novel electronic control technologies and high-power switch devices, and lithium battery management systems lay a foundation for further improving the dynamic quality of electric vehicles and prolonging the service life of lithium battery packs. However, phenomena such as short cycle life and fast aging speed of lithium batteries frequently appear during use. To understand the operating conditions of lithium batteries, people pay close attention to the health and safety of lithium batteries. In order to make a lithium-ion battery reflect the operating state in time during the application process, performing on-line real-time monitoring and prediction on the state of charge (SOC), state of health (SOH), and remaining useful life (RUL) of the lithium-ion battery has become one of the critical parts of an overall battery system. The lithium battery's SOC can reflect the remaining power of the battery, and a study on the on-line monitoring of the SOH of the lithium battery can further predict the RUL of the battery so that incidents can be prevented in time. Therefore, the on-line monitoring of the SOC and SOH of the lithium battery and the on-line prediction of the RUL is critical to the lithium battery's safe application.

The SOC, SOH, and RUL of the lithium battery are all defined through capacity. However, since the lithium battery's capacity cannot be directly measured during practical application and can only be obtained by indirect calculation, accurate capacity estimation becomes a big challenge. Capacity estimation methods can be divided into two categories: model-based methods and data-driven based methods. The model-based methods usually use electrochemical models and equivalent circuit models to combine a priori knowledge of the life cycle with the equivalent mechanism of the physical and chemical reactions occurring in the battery to calculate the capacity. However, the model-based methods' model parameters are mostly obtained by calculation using some simplified assumptions and are not suitable for changes in complex operating conditions. The data-driven based methods are improved day by day in availability due to a large amount of battery data and are widely used to estimate lithium batteries' capacity since there is no need to understand the aging battery dynamics comprehensively. In recent years, a method using a neural network has attracted significant attention in battery capacity estimation. The present invention provides a lithium battery capacity estimation method based on a convolution long-short-term memory neural network, which implements accurate estimation and prediction of battery capacity.

### SUMMARY

Given this, the present invention's purpose is to provide a lithium battery capacity estimation method based on an improved convolution long-short-term memory neural network (CNN-LSTM).

To achieve the above purpose, the present invention provides the following technical solution: A method of lithium battery capacity estimation based on a convolution long-short-term memory neural network, comprising the following steps:

S1: collecting data: collecting charging and discharging data of a real lithium battery by a sensor, including discharging voltage, discharging current, body temperature, and capacity;

S2: performing signal decomposition on collected original discharging data of a battery using an empirical mode decomposition (EMD) algorithm, that is, denoising sequence data;

S3: selecting optimal hyper-parameters of an improved CNN-LSTM using a genetic algorithm;

S4: taking data after EMD in step S2 as training data of a neural network, building an improved CNN-LSTM model in combination with optimal hyper-parameters of a neural network selected in step S3;

S5: inputting the discharging data of the lithium battery collected by the sensor into a trained network model for testing, thus obtaining battery capacity estimated by the model;

S6: judging whether the neural network's output result is correct or not according to a root mean square error (RMSE), if it is correct, outputting a result, otherwise, supplementing the training data, and readjusting the hyper-parameters of the network.

Optionally, in step S2, the performing signal decomposition on collected original discharging data of a battery using an empirical mode decomposition algorithm specifically comprises the following steps:

S21: calculating upper and lower envelopes respectively according to upper and lower extreme points of an original signal;

S22: calculating a mean of the upper and lower envelopes, and drawing a mean envelope;

S23: subtracting the mean envelope from the original signal to obtain an intermediate signal;

S24: judging whether the intermediate signal meets the two conditions of IMFs, if so, the signal is an IMF component; otherwise, re-analyzing S21-S24 based on the signal, wherein the acquisition of the IMF component usually requires several iterations;

S25: after a first IMF is obtained using the above method, subtracting the IMF1 from the original signal as a new original signal, then analyzing S21-S24 to obtain an IMF2, and so on, completing the EMD.

Optionally, step S3 specifically comprises the following steps: S31: selecting a population size and encoding each individual in a population, wherein the individual is composed of various hyper-parameters of the neural network, and the hyper-parameters thereof are randomly selected within a value range;

S32: writing a fitness function, decoding the individuals, and taking the hyper-parameters obtained from the individuals as initial hyper-parameters of the neural network; calculating the sum of absolute errors between a predicted output of the neural network model and an actual output, and taking same as a fitness value;

S33: in the selection operation, selecting a roulette algorithm; and taking a reciprocal of the fitness value, the smaller the individual fitness value, the greater the probability of being selected;

S34: in the crossover operation, selecting an individual according to crossover probability using a real number crossover method, and crossing chromosomes at any two positions of the selected individual and individuals adjacent to that;

S35: in the mutation operation, using uniform mutation and selecting mutational individuals by setting mutation probability.

Optionally, step S6 specifically comprises the following steps: calculating a root mean square error (RMSE),

$$RMSE = \sqrt{\frac{1}{N} {\sum }_{i = 0}^{N} {( {c}_{i} - {c}_{i} )}^{2}} ,$$

and evaluating an output effect of the neural network.

The present invention has the advantageous effects that: according to the present invention, the improved convolution long-short-term memory neural network is applied to lithium battery capacity estimation, and according to the method, the original charging and discharging data of the lithium battery are analyzed using the empirical mode decomposition algorithm, and the original data are denoised. The genetic algorithm is used to adjust the neural network's hyper-parameters to build a neural network model to estimate the capacity of a lithium battery accurately, thereby achieving the on-line estimation and prediction of the SOC, SOH, and RUL of the lithium battery, having great application significance.

Other advantages, objectives, and features of the present invention will be illustrated in the following description and will be apparent to those skilled in the art based on the subsequent investigation and research to some extent or taught from the present invention practice. The objectives and other advantages of the present invention can be realized and obtained through the following description.

### DESCRIPTION OF DRAWINGS

To enable the purpose, the technical solution and the advantages of the present invention to be more clear, the present invention will be preferably described in detail below in combination with the drawings, wherein:

FIG. 1 is a flow chart of an overall technical solution;

FIG. 2 is a flow chart of an algorithm of a neural network optimized using a genetic algorithm;

FIG. 3 is a structural diagram of an improved convolution long-short-term memory neural network;

FIG. 4 is a structural diagram of an improved long short term memory neural network.

### DETAILED DESCRIPTION

Embodiments of the present invention are described below through specific embodiments. Those skilled in the art can understand other advantages and effects of the present invention easily by disclosing of the description. The present invention can also be implemented or applied through additional different specific embodiments. All details in the description can be modified or changed based on different perspectives and applications without departing from the present invention's spirit. It should be noted that the figures provided in the following embodiments only exemplarily explain the basic conception of the present invention, and if there is no conflict, the following embodiments and the features in the embodiments can be mutually combined.

The drawings are only used for exemplary description, are only schematic diagrams rather than physical diagrams, and shall not be understood as a limitation to the present invention. In order to better illustrate the embodiments of the present invention, some components in the drawings may be omitted, scaled up or scaled-down, and do not reflect actual product sizes. It should be understandable for those skilled in the art that some well-known structures and descriptions in the drawings may be omitted.

Same or similar reference signs in the drawings of the embodiments of the present invention refer to the same or similar components. It should be understood in the description of the present invention that terms such as “upper”, “lower”, “left”, “right”, “front” and “back” indicate direction or position relationships shown based on the drawings, and are only intended to facilitate the description of the present invention and the simplification of the description rather than to indicate or imply that the indicated device or element must have a specific direction or constructed and operated in a specific direction, and therefore, the terms describing position relationships in the drawings are only used for exemplary description and shall not be understood as a limitation to the present invention; for those ordinary skilled in the art, the above terms' meanings may be understood according to specific conditions.

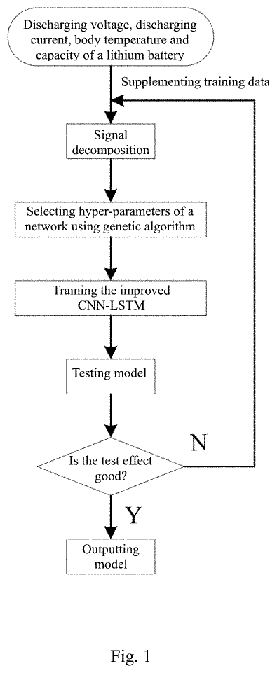

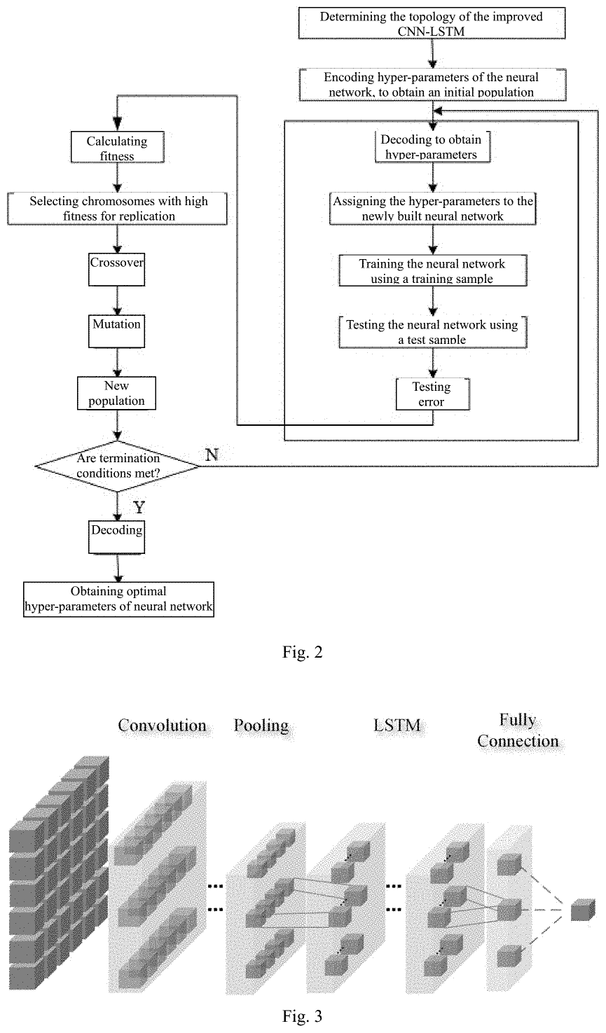

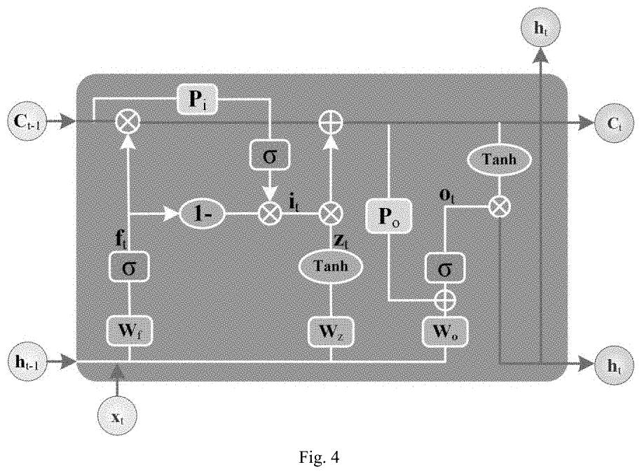

Refer to FIGS. 1-4, which shows a method for estimating lithium battery capacity based on a convolution long-short-term memory neural network.

1. Collecting data: collecting charging and discharging data of a real lithium battery by a sensor, including discharging voltage, discharging current, body temperature, and capacity;

2. To achieve SOC monitoring, the following five steps are required:

a) performing signal decomposition on collected original data of discharging voltage, discharging current and body temperature of the battery using an EMD algorithm, that is, denoising sequence data;

b) selecting optimal hyper-parameters of an improved CNN-LSTM using a genetic algorithm;

c) taking data after EMD in step a) as training data of a neural network, building an improved CNN-LSTM model in combination with optimal hyper-parameters of a neural network selected in step b);

d) inputting the discharging voltage, discharging current, and body temperature of the lithium battery collected by the sensor into a trained network model for testing, thus obtaining a SOC value estimated by the model;

e) judging whether the neural network's output result is correct or not according to an RMSE, if it is correct, outputting the result, otherwise, supplementing the training data, and readjusting the hyper-parameters of the network.

3. To achieve SOH monitoring, the following five steps are required:

a) performing signal decomposition on collected original data of discharging voltage, discharging current, and body temperature of the battery using an EMD algorithm, that is, denoising sequence data;

b) selecting optimal hyper-parameters of an improved CNN-LSTM using a genetic algorithm;

c) taking data after EMD in step a) as training data of a neural network, building an improved CNN-LSTM model in combination with optimal hyper-parameters of a neural network selected in step b);

d) inputting the discharging voltage, discharging current, and body temperature of the lithium battery collected by the sensor into a trained network model for testing, thus obtaining a SOH value estimated by the model, the forward computing formulae of the improved LSTM being as follows:

fₜ=sigmoid(W_{fx}·x_{f}+W_{fh}·hₜ₋₁+b_{f})

zₜ=tan h(W_{zx}·xₜ+W_{zh}·hₜ₋₁+b_{z})

iₜ=(1−fₜ)□sigmoid(cₜ₋₁□pᵢ)

cₜ=cₜ₋₁□fᵢ+iₜ□zₜ

oₜ=sigmoid(Wₒₓ·xₜ+Wₒₕ·hₜ₋₁+pₒ□cₜ+bₒ)

hₜ=oₜ□ tan h(cₜ)

e) judging whether the output result of the neural network is correct or not according to an RMSE, if it is correct, outputting the result, otherwise, supplementing the training data, and readjusting the hyper-parameters of the network, the computing formula of the RMSE being as follows:

$$RMSE = \sqrt{\frac{1}{N} {\sum }_{i = 0}^{N} {( {c}_{i} - {c}_{i} )}^{2}} ,$$

4. To achieve RUL prediction, the following five steps are required:

a) performing signal decomposition on collected original data of the battery's capacity using an EMD algorithm, that is, denoising sequence data.

b) selecting optimal hyper-parameters of an improved CNN-LSTM using a genetic algorithm;

c) taking data after EMD in step a) as training data of a neural network, building an improved CNN-LSTM model in combination with optimal hyper-parameters of a neural network selected in step b);

d) inputting the discharging voltage, discharging current, and body temperature of the lithium battery collected by the sensor into a trained network model for testing, thus obtaining a capacity value predicted by the model;

e) judging whether the neural network's output result is correct or not according to an RMSE, if it is correct, outputting the result, otherwise, supplementing the training data, and readjusting the hyper-parameters of the network.

Finally, it should be noted that the above embodiments are only used for describing, rather than limiting, the technical solution of the present invention. Although the present invention is described in detail about the preferred embodiments, those ordinary skilled in the art shall understand that the technical solution of the present invention can be amended or equivalently replaced without departing from the purpose and the scope of the technical solution. The amendment or equivalent replacement shall be covered within the scope of the claims of the present invention.

1. A method of lithium battery capacity estimation based on a convolution long-short-term memory neural network, comprising following steps:
S1: collecting data: collecting charging and discharging data of a real lithium battery by a sensor, including discharging voltage, discharging current, body temperature, and capacity;
S2: performing signal decomposition on collected original discharging data of a battery using an empirical mode decomposition (EMD) algorithm, that is, denoising sequence data;
S3: selecting optimal hyper-parameters of an improved CNN-LSTM using a genetic algorithm;
S4: taking data after EMD in step S2 as training data of a neural network, building an improved CNN-LSTM model in combination with optimal hyper-parameters of a neural network selected in step S3;
S5: inputting the discharging data of the lithium battery collected by the sensor into a trained network model for testing, thus obtaining battery capacity estimated by the model;
S6: judging whether an output result of the neural network is correct or not according to a root mean square error (RMSE), if it is correct, outputting the result, otherwise, supplementing the training data, and readjusting the hyper-parameters of the network.

2. The method of lithium battery capacity estimation based on a convolution long-short-term memory neural network according to claim 1, characterized in that in step S2, the performing signal decomposition on collected original discharging data of a battery using an empirical mode decomposition algorithm comprises explicitly following steps:
S21: calculating upper and lower envelopes respectively according to upper and lower extreme points of an original signal;
S22: calculating a mean of the upper and lower envelopes, and drawing a mean envelope;
S23: subtracting the mean envelope from the original signal to obtain an intermediate signal;
S24: judging whether the intermediate signal meets the two conditions of IMFs, if so, the signal is an IMF component; otherwise, re-analyzing S21-S24 based on the signal, wherein the acquisition of the IMF component usually requires several iterations;
S25: after a first IMF is obtained using the above method, subtracting the IMF1 from the original signal as a new original signal, then analyzing S21-S24 to obtain an IMF2, and so on, completing the EMD.

3. The method of lithium battery capacity estimation based on a convolution long-short term memory neural network according to claim 1, characterized in that step S3 specifically comprises following steps:
S31: selecting a population size and encoding each individual in a population, wherein the individual is composed of various hyper-parameters of the neural network, and the hyper-parameters thereof are randomly selected within a value range;
S32: writing a fitness function, decoding the individuals, and taking the hyper-parameters obtained from the individuals as initial hyper-parameters of the neural network; calculating the sum of absolute errors between a predicted output of the neural network model and an actual output, and taking same as a fitness value;
S33: in a selection operation, selecting a roulette algorithm; and taking a reciprocal of the fitness value, the smaller the individual fitness value, the greater the probability of being selected;
S34: in a crossover operation, selecting an individual according to crossover probability using a real number crossover method, and crossing chromosomes at any two positions of selected individual and individuals adjacent to that;
S35: in a mutation operation, using uniform mutation and selecting mutational individuals by setting mutation probability.

4. The method of lithium battery capacity estimation based on a convolution long-short-term memory neural network according to claim 1, characterized in that step S6 specifically comprises following steps: calculating a root mean square error (RMSE),
$$RMSE = \sqrt{\frac{1}{N} {\sum }_{i = 0}^{N} {( {c}_{i} - {c}_{i} )}^{2}} ,$$
and evaluating an output effect of the neural network.
